(19) United States
(12) Patent Application Publication
(10) Pub. No.: US 2006/0037934 A1
(43) Pub. Date: Feb. 23, 2006

(54) Manufacturing method for organic electronic device

(76) Inventors: Mitsuru Suginoya, Chiba-shi (JP); Masayuki Suda, Chiba-shi (JP); Shuhei Yamamoto, Chiba-shi (JP)

Correspondence Address: BRUCE L. ADAMS, ESQ., SUITE 1231, 17 BATTERY PLACE, NEW YORK, NY, 10004, US

(21) Appl. No.: 11/196,098

(22) Filed: Aug. 3, 2005

(30) Foreign Application Priority Data
Aug. 17, 2004 (JP) 2004-236940

(51) Int. Cl. H01B 13/00

(52) U.S. Cl. 216/13; 427/66

(57) ABSTRACT

A manufacturing method permits easy manufacture of an organic electronic device using an extremely thin substrate. The manufacturing method includes a first step for polishing a first surface of a substrate, a second step for providing a protective polymeric layer on the first surface, a third step for etching a second surface on the back side of the first surface of the substrate to make the substrate thinner, a fourth step for providing a polymeric layer that contains a polymeric material on the etched second surface, a fifth step for removing the protective polymeric layer, and a sixth step for forming an organic electronic device on the first surface from which the protective polymeric layer has been removed.

### BACKGROUND OF THE INVENTION

1. Field of the Invention

The present invention relates to a manufacturing method for an organic electronic device using a flexible substrate, such as an organic electroluminescent (EL) device or an organic semiconductor device.

2. Description of the Related Art

With the recent trend toward an intensified ubiquitous environment, there has been an increasing expectation for applying organic electronic devices that use flexible substrates to ubiquitous electronic equipment that supports such a ubiquitous environment. Organic EL devices, in particular, permit luminescence at a lower voltage than inorganic EL devices. Moreover, organic EL devices are self-luminescent, exhibiting high visibility, and are expected to be used as the displays or luminescent sources for ubiquitous electronic equipment by using flexible substrates.

However, most high polymer materials frequently used for flexible substrates have slight moisture permeability, because their constituents are organic matters. In many cases, minute quantities of moisture cause organic EL devices and other organic electronic devices to deteriorate with consequent damage to their characteristics. It has been a significant challenge, therefore, to block moisture passing through substrates in order to achieve commercial use of organic electronic devices employing high polymers for their substrates.

As an effective method for solving the problem described above, a method that uses a substrate combining an extremely thin glass substrate and a high-polymer film has been disclosed in Japanese Unexamined Patent Application Publication No. 11-329715 (Patent Literature 1). A glass substrate itself has no moisture permeability, whereas it lacks flexibility and breaks if subjected to even a slight bending stress. It has been widely accepted, however, that the breakage of glass is not a matter of the strength of a glass material itself, but numerous scratches on a surface thereof lead to breakage from application of even a weak force. The resistance of the glass to a bending stress can be significantly improved by covering one surface of the glass with a high polymer material, as disclosed in Technical Literature 1. However, when it comes to a specific manufacturing method for such a composite substrate, Patent Document 1 simply describes “glass of about 30 μm available from DESAG AG (Germany), etc. is still extremely difficult to handle and extremely fragile, requiring utmost careful handling” (31st to 34th lines of page 4). The document describes that sufficient strength can be obtained after combining materials, but it neither refers to how to securely fabricate the composite material nor discloses how to handle thin, fragile glass during its manufacturing process.

Thus, if an extremely thin glass substrate is used from the beginning to fabricate a composite material containing a high polymer, damage to the glass substrate is unavoidable even if the glass is handled with utmost carefulness. This means an extremely low manufacturing yield is expected.

Furthermore, an attempt to increase the size of a substrate to fabricate a large screen display or to maximize the number of pieces that can be taken from a single substrate so as to improve productivity would face a difficulty of successfully making an extremely thin glass with a large area. Even if such large, extremely thin glass could be fabricated, the glass would be obviously very difficult to handle in the manufacturing process.

The problems described above have been making it very difficult to provide such superb performance at reasonable cost in the market.

### SUMMARY OF THE INVENTION

Accordingly, in order to easily fabricate a flexible substrate that combines glass and a high polymer, a manufacturing method for an organic electronic device in accordance with the present invention includes a first step for polishing a first surface of a substrate, a second step for providing a protective polymeric layer on the first surface, a third step for removing a second surface on the back side of the first surface by etching so as to make the substrate thinner, a fourth step for providing a polymeric layer that contains a polymeric material on the etched second surface, a fifth step for removing the protective polymeric layer, and a sixth step for forming an organic electronic device on the first surface from which the protective polymeric layer has been removed.

The polymeric layer uses a film, the chief ingredient thereof being any one of an aliphatic or alicyclic polyimide resin, a polyamide-imide resin, a thermosetting vinylester resin, a thermosetting bisphenol A resin, and a cardo resin. The film is formed on the second surface of the substrate by coating. Alternatively, the polymeric layer uses a polymeric film, the chief ingredient thereof being any one of polyethylene terephthalate, polyethylene naphthalate, polycarbonate, polyarylate, polyether sulfone, polysulfone, polyetherimide, polyimide, polyamide, cyclic olefin polymer or a copolymer thereof, a thermosetting vinylester resin, and a thermosetting bisphenol A resin. The polymeric film is bonded onto the second surface of the substrate by an adhesive agent.

Furthermore, the protective polymeric layer contains, as its chief ingredient, any one of polyethylene terephthalate, polyethylene naphthalate, polycarbonate, polyarylate, polyether sulfone, polysulfone, polyetherimide, polyimide, polyamide, cyclic olefin polymer or a copolymer thereof, a thermosetting vinylester resin, a thermosetting bisphenol A resin, an acrylic resin, and a phenol novolak resin.

For the substrate, a glass substrate having a thickness of 0.3 mm or more is used and the thickness is reduced to 0.2 mm or less in the third step.

The flexible organic electronic device fabricated easily on a smooth surface of a substrate by the simple method described above exhibits high performance, while being immune to deterioration from moisture permeating through the substrate. Moreover, the flexibility of the substrate makes it possible to achieve a device with high strength that survives bending.

### BRIEF DESCRIPTION OF THE DRAWINGS

FIG. 1A to 1E are schematic diagrams showing a manufacturing method for the substrate for an organic electronic device in accordance with the present invention; and

FIG. 2 is a schematic diagram showing the organic electronic device in accordance with the present invention.

### DETAILED DESCRIPTION OF THE PREFERRED EMBODIMENTS

The manufacturing method for an organic electronic device in accordance with the present invention includes a first step for polishing a first surface of a substrate, a second step for providing a protective polymeric layer on the first surface, a third step for etching a second surface at the back side of the first surface so as to make the substrate thinner, a fourth step for providing a polymeric layer that contains a polymeric material on the etched second surface, a fifth step for removing the protective polymeric layer, and a sixth step for forming an organic electronic device on the first surface from which the protective polymeric layer has been removed.

The surface of the substrate on which organic electronic devices are to be formed has to be flat and smooth, so that the polishing carried out in the first step is important. The limit of a practical substrate thickness that can be introduced in the polishing step is 0.3 mm. As the substrate, a substrate having a thickness of 0.3 mm or more that permits a large area and survives handling in the is manufacturing process has been selected. As a material for the substrate, mainly soda glass, borosilicic acid glass, or non-alkali glass may be selected according to an individual application.

Further, to protect the planarized surface in subsequent steps and to retain the glass that has been processed to be thinner, i.e., to reinforce the strength of the glass, so as to allow the subsequent steps to be stably carried out, the protective polymeric layer is provided on the polished surface in the second step. As the materials for the protective polymeric layer, polymeric materials and composite materials of polymeric materials and inorganic compounds or the like may be used. The protective polymeric layer may be formed by coating the materials onto the substrate or a film composed of such materials may be bonded to the substrate. The protective film is formed on the glass substrate, which is still thick, so that the potential of damage to the glass substrate described above can be avoided.

Then, with the planarized surface protected, the opposite surface of the substrate is etched to decrease the thickness of the substrate. When the thickness of a glass substrate is decreased to 0.1 mm or less, the glass substrate develops marked flexibility although it varies, depending on the type of glass. Taking all types of glass into account, the flexibility is considered to be developed when the thickness is 0.2 mm or less. In this condition wherein the glass and polymeric materials are compounded, an organic electronic device using a substrate having flexibility and high strength in accordance with the present invention is achieved. In this condition, however, the glass surface on which the organic electronic devices are to be formed is the etched surface, which inherently lacks planarity, thus leading to defective organic electronic devices. It may be possible to form the organic electronic devices on the polymeric surface. However, in comparison with glass, polymeric materials incur considerable thermal expansion and contraction, so that the accuracy of minute organic electronic devices cannot be ensured with consequent irregular characteristics. For this reason, according to the present invention, the polymeric layer is deposited on the etched surface of the substrate, then the protective polymeric layer is removed to expose the polished surface of the glass so as to form the organic electronic devices on the surface. This allows the polished glass surface to provide the surface on which the organic electronic devices are to be formed.

The polymeric layer is composed primarily of a polymer, and inorganic particulates or the like, such as filler, may be added, as necessary. The layer may be formed by coating or by bonding a film. At this time, the protective polymeric layer formed on the polished surface serves as a film that supports the extremely thin glass to protect the substrate from damage during the process. In the next fifth step, the protective coating or the protective film that has protected the polished surface of the substrate up to that moment is peeled and removed to expose the polished surface of the substrate. From this step and after, the polymeric film formed on the etched surface takes over the function of the film that supports the extremely thin substrate.

The following will explain in further detail the manufacturing method for an organic electronic device in accordance with the present invention.

### First Embodiment

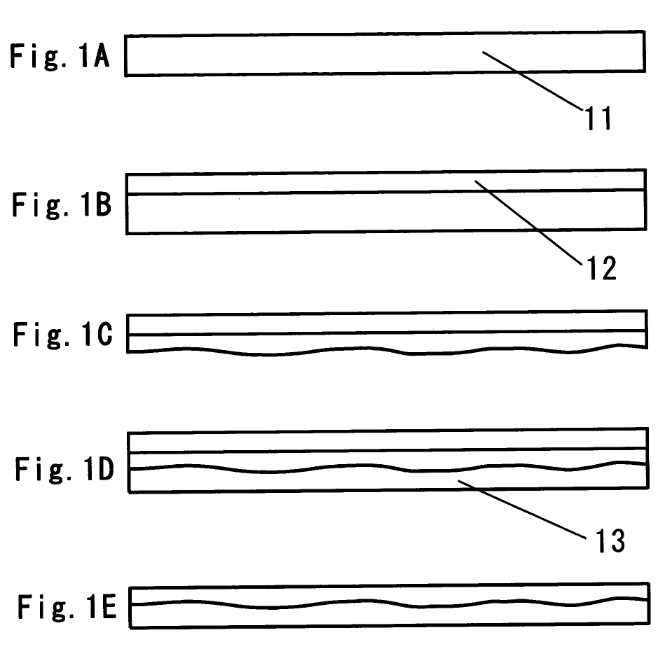

FIG. 1 schematically shows the manufacturing method for an organic electronic device according to the present embodiment. FIG. 1A is a sectional view of a substrate 11. In the present embodiment, no-alkali glass having a thickness of 0.5 mm has been used. At least one surface of the glass has been polished using a lapping film or an abrasive to planarize it, the profile irregularity thereof being 0.1 μm or less.

FIG. 1B is a sectional view showing a protective polymeric layer 12 that has been provided on the planarized surface, i.e., the polished surface of the substrate 11. The protective polymeric layer may be formed by laminating or the like, using a polymeric film and a bonding agent. The polymeric film may be composed of polyethylene terephthalate, polyethylene naphthalate, polycarbonate, polyarylate, polyether sulfone, polysulfone, polyetherimide, or the like. For the adhesive layer, an acrylic resin, a silicon resin or the like may be used. Preferably, the adhesive layer used for this purpose is a type that loses its adhesiveness when subjected to light, heat or a solvent or the like so as to permit easy removal of the adhesive layer in the peeling step, which will be discussed hereinafter.

Referring to FIG. 1C, the substrate 11 with the protective polymeric layer 12 formed thereon is immersed in an etchant composed of hydrofluoric acid or the like, and glass etching is carried out to decrease the thickness to 0.15 mm. In this condition, the glass itself is fragile, so that an attempt to peel off the protective polymeric layer would easily break the substrate.

In FIG. 1D, a film having one of an aliphatic or alicyclic polyimide resin, a polyamide-imide resin, a thermosetting vinylester resin, a thermosetting bisphenol A resin, and a cardo resin as its chief ingredient is formed on the etched surface of the substrate 11, which has undergone etching.

As an example of the aliphatic or alicyclic polyimide resin, a solution prepared by dissolving a polymer obtained by polycondensation of aliphatic tetracarboxylic acid and aromatic diamine into y-butyrolactone is used. To improve adhesion to glass, an additive, such as a coupling agent, may be mixed into the solution, as necessary. Examples of a polyamide imide resin include VYLOMAX® made by Toyobo. Examples of the thermosetting vinylester resin include Super polyester SSP series made by Showa Highpolymer. Examples of the thermosetting bisphenol A resin include Rigolight® 500 made by Showa Highpolymer. Examples of the cardo resin include V-259 made by Nippon Steel Chemical Group.

These materials were applied onto the substrate by a roll coater, a bar coater, a slit coater, or the like and subjected to a curing process, as necessary, by heat curing or ultraviolet curing or the like, thus forming a polymeric layer 13. The film thickness of the polymeric layer 13 was set to 50 μm.

Referring to FIG. 1E, by exposure to light or heat or by immersion in a solvent, or with the aid of a mechanical removing device, the protective polymeric layer 12 is removed to expose the polished surface of the substrate 1. In this step, the glass substrate is protected with the 50-μm polymeric layer to protect the glass substrate from damage in the peeling step.

Thus, the flexible substrate for an organic electronic device has been fabricated. The substrate is light-weight and resistant to bending, the polished glass surface maintaining the planar surface.

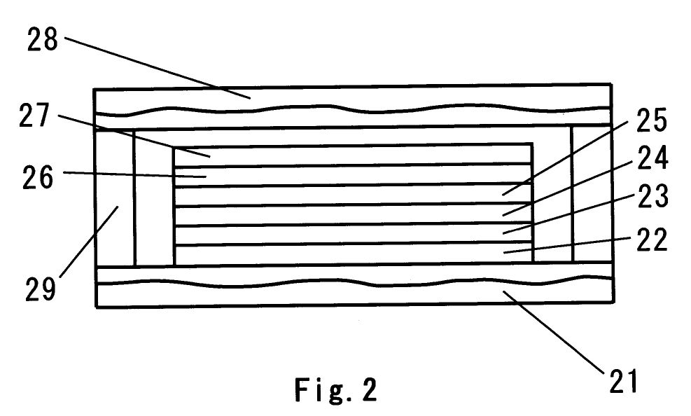

FIG. 2 shows an organic EL device, which is an example of an organic electronic device, fabricated using the substrate in accordance with the present invention. Referring to FIG. 2, a substrate 21 has been produced using the method illustrated in FIG. 1 described above. An anode 22 formed by a transparent conductive film composed of ITO, IZO or the like is deposited on the substrate 21 by a process, such as sputtering, vapor deposition, or CVD. The surface on which the anode is deposited is the glass surface, so that the anode can be deposited without the need for any special processing except for cleaning. Deposited on the anode 22 by vacuum deposition are a hole injection layer 23 composed of a copper phthalocyanine or an aromatic amine and a hole transport layer 24 composed of α-NPD, TPD derivative, or the like, which is also an aromatic amine. Further, a layer that has a host material composed of a metal complex or the like of 8-hydroxyquinoline derivative, such as Alq3, BAlq3 or Bebq2, and contains a fluorescent pigment, e.g., perylene, quinacridone, coumarine, rubrene or DCJTB, as a dopant is deposited as a luminescent layer 25 on the hole transport layer 24 by co-deposition. In addition, an electron transport layer 26 composed of Alq3, Bebq2 or the like, and a cathode 27 having Al deposited on a LiF thin film are formed by vacuum deposition.

A flexible substrate 28 combining glass and a polymeric material as in the substrate on which the organic EL layer has been formed is bonded and sealed by a sealant 29, thereby completing an organic EL device.

The organic EL device fabricated as described above exhibits stable luminescence property, which is free from deterioration caused by permeation of moisture, and also features high flexibility and portability, whereas it can be produced by the simple, practical method.

### Second Embodiment

The present embodiment will be explained in conjunction with FIG. 1. A substrate 11 shown in FIG. 1A is composed of borosilicate glass having a thickness of 0.4 mm. At least one surface of the glass has been polished using a lapping film or an abrasive to planarize it, the profile irregularity thereof being 0.1 μm or less.

Referring to FIG. 1B, a coating film composed of a polymeric material containing any one of polyimide, polyamide, cyclic olefin polymer or a copolymer thereof, a thermosetting vinylester resin, a thermosetting bisphenol A resin, an acrylic resin, and a phenol novolak resin as its chief ingredient is formed on the polished surface of the substrate 11. These polymeric materials are in the form of a solution or a precursor solution and applied onto the substrate by a roll coater, a bar coater, a slit coater or the like, and then subjected to curing, as necessary, by drying and solidifying, heat curing, ultraviolet curing or the like so as to form a protective polymeric layer 12. The film thickness of the protective polymeric layer 12 was set to 100 μm; however, the film thickness is not limited thereto as long as it ensures adequate reinforcement of the glass, which has been made thinner. The protective polymeric layer used for this purpose is preferably a type that is easily dissolved or removed by exposure to light or heat or immersion in a solvent or the like in order to permit easy removal, which will be discussed hereinafter.

Referring to FIG. 1C, the substrate 11 with the protective polymeric layer 12 formed thereon is immersed in an etchant composed of hydrofluoric acid or the like, and glass etching is carried out to decrease the thickness to 0.1 mm. In this condition, the glass itself is fragile, so that an attempt to peel off the protective polymeric layer would easily break the substrate.

Referring to FIG. 1D, a polymeric film is bonded onto the etched surface of the etched glass substrate 11 by an adhesive agent, thereby forming a polymeric layer 13. The chief ingredient of the polymeric film is any one of polyethylene terephthalate, polyethylene naphthalate, polycarbonate, polyarylate, polyether sulfone, polysulfone, polyetherimide, polyimide, polyamide, cyclic olefin polymer or a copolymer thereof, a thermosetting vinylester resin, and a thermosetting bisphenol A resin.

Examples of a polyethylene terephthalate film include TEFLEX® made by Teijin, examples of a polyethylene naphthalate film include Teonex® made by Teijin, and examples of a polycarbonate film include Panlite® made by Teijin. Examples of a polyarylate film include Crystalate® made by Kanegafuchi Chemical Industry, examples of a polyether sulfone film include SUMILITE® FS-1300 made by Sumitomo Bakelite, and examples of a polysulfone film include SUMILITE® FS-1200 made by Sumitomo Bakelite. Examples of a polyetherimide film include SUPERIOR made by Mitsubishi Jushi, examples of a polyimide film include a fluorinated polyimide made by Kanegafuchi Chemical. Industry, and examples of a polyamide film include a nylon film. Examples of a cyclic olefin polymer or a film of a copolymer thereof include ARTON® made by JSR and ZEONOA® made by Nippon Zeon. Examples of a thermosetting vinylester resin film include Rigolight® made by Showa Highpolymer, and examples of a thermosetting bisphenol A resin include Rigolight® 500 made by Showa Highpolymer.

These materials are bonded to the substrate by an acrylic type or silicone type adhesive agent. The adhesive agent used preferably exhibits high adhesion to a glass substrate. The bonded film provides the polymeric layer 13, the film thickness of the polymeric layer 13 being 100 μm.

Referring to FIG. 1E, the protective polymeric layer 12 is peeled off by subjecting it to light or heat or immersing it in a solvent or with the aid of a mechanical removing means so as to expose the polished surface of the substrate 1. Because of the 100-μm polymeric film protecting the glass substrate, no damage to the glass substrate was observed in this step.

Thus, the flexible substrate for an organic electronic device has been fabricated. The substrate is light-weight and resistant to bending, the polished glass surface maintaining the planar surface.

Thereafter, an organic EL device was fabricated in the same manner as in the first embodiment, and the same advantages as those of the first embodiment have been obtained.

Organic EL devices, which are examples of the organic electronic devices shown in the embodiments, may be used for a curve light source of an automotive dashboard. Furthermore, their light weight and thin design are most likely to make the organic EL devices play a leading part in the man-machine interface field in future electronic equipment, including a portable ubiquitous display, such as the monitor of a ground wave digital receiver, a portable browser, and a digital camera or video camera.

What is claimed is:

1. A manufacturing method for an organic electronic device, comprising:
a first step for polishing a first surface of a substrate;
a second step for providing a protective polymeric layer on the first surface;
a third step for removing a second surface at the back side of the first surface of the substrate by etching so as to make the substrate thinner;
a fourth step for providing a polymeric layer that contains a polymeric material on the etched second surface;
a fifth step for removing the protective polymeric layer; and
a sixth step for forming an organic electronic device on the first surface from which the protective polymeric layer has been removed.

2. The manufacturing method for an organic electronic device according to claim 1, wherein the substrate is a glass substrate having a thickness of 0.3 mm or more, and the thickness is reduced to 0.2 mm or less in the third step.

3. The manufacturing method for an organic electronic device according to claim 1, wherein the polymeric layer is a film, the chief ingredient thereof being any one of an aliphatic or alicyclic polyimide resin, a polyamide-imide resin, a thermosetting vinylester resin, a thermosetting bisphenol A resin, and a cardo resin, and the film is formed by coating.

4. The manufacturing method for an organic electronic device according to claim 1, wherein the polymeric layer is a polymeric film, the chief ingredient thereof being any one of polyethylene terephthalate, polyethylene naphthalate, polycarbonate, polyarylate, polyether sulfone, polysulfone, polyetherimide, polyimide, polyamide, cyclic olefin polymer or a copolymer thereof, a thermosetting vinylester resin, and a thermosetting bisphenol A resin, and the polymeric film is bonded onto the second surface by an adhesive agent.

5. The manufacturing method for an organic electronic device according to claim 1, wherein the protective polymeric layer contains, as the chief ingredient thereof, any one of polyethylene terephthalate, polyethylene naphthalate, polycarbonate, polyarylate, polyether sulfone, polysulfone, polyetherimide, polyimide, polyamide, cyclic olefin polymer or a copolymer thereof, a thermosetting vinylester resin, a thermosetting bisphenol A resin, an acrylic resin, and a phenol novolak resin.

6. The manufacturing method for an organic electronic device according to claim 1, wherein an organic electronic device formed on the first surface from which the protective polymeric layer has been removed is an organic EL device.
